(19) United States
(12) Patent Application Publication
(10) Pub. No.: US 2007/0278603 A1
(43) Pub. Date: Dec. 6, 2007

(54) Magnetic memory device and method for fabricating the same

(75) Inventors: Takao Ochiai, Kawasaki (JP); Shinjiro Umehara, Kawasaki (JP); Hiroshi Ashida, Kawasaki (JP); Masashige Sato, Kawasaki (JP); Yutaka Shimizu, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/633,588

(22) Filed: Dec. 5, 2006

(30) Foreign Application Priority Data
May 31, 2006 (JP) 2006-151253

(51) Int. Cl. H01L 43/00

(52) U.S. Cl. 257/421

(57) ABSTRACT

The magnetic memory device comprises a recording layer 70 formed linearly over a substrate 10 and having a plurality of pinning sites 52 for restricting the motion of domain walls 50 formed at a prescribed pitch and having the regions between the plural pinning sites 52 as recording bits 72. The recording layer 70 includes a first recording layer portion 46 and a second recording layer portion 68, and the second recording layer portion 68 is positioned above the first recording layer portion 46 and has one end connected to one end of the first recording layer portion 46. The second recording layer portion 68 is formed above the first recording layer portion 46, and the end of the second recording layer portion 68 is connected to one end of the first recording layer portion 46, whereby the space required to form the recording layer 70 can be small.

### CROSS-REFERENCE TO RELATED APPLICATION

This application is based upon and claims priority of Japanese Patent Application No. 2006-151253, filed on May 31, 2006, the contents being incorporated herein by reference.

### BACKGROUND OF THE INVENTION

The present invention relates to a magnetic memory device and a method for fabricating the magnetic memory device, more specifically, a magnetic memory device including linear recording layers and a method for fabricating the magnetic memory device.

Recently, as a rewritable nonvolatile memory, the magnetic random access memory (hereinafter called “MRAM”), which magnetoresistance effect elements laid out in a matrix, is noted. The MRAM utilizes combinations of magnetization directions of two magnetic layers to store information and detects resistance changes (i.e., current or voltage changes) given when the magnetization directions of the magnetic layers are parallel with each other and anti-parallel with each other to read the stored information.

As the magnetoresistance effect elements forming the MRAM, GMR (Giant MagnetoResistive) elements and TMR (Tunneling MagnetoResistive) elements are known. Among them, the TMR elements, which give large resistance changes, is noted as the magnetoresistance effect elements used in the MRAM. The TMR element includes two ferromagnetic layers laid one on another with a tunnel insulation film to utilize the phenomena that the tunnel current flowing between the magnetic layers through the tunnel insulation film changes based on relationships between the magnetization directions of the two ferromagnetic layers. That is, the TMR element has low element resistance when the magnetization directions of the two ferromagnetic layers is parallel with each other, and has high element resistance when the magnetization directions of the two ferromagnetic layer is anti-parallel with each other. These two states are related to data “0” and data “1”, whereby the TMR element can be used as the memory element.

Recently, a technique is proposed that a U-shaped recording layer for recording information is formed vertically to a substrate, and restriction regions for restricting the motion of the domain walls are formed in the recording layer at a prescribed pitch, whereby information is written in or read from the respective recording bits defined by such restriction regions (Patent Reference 1).

Following references disclose the background art of the present invention.

[Patent Reference 1]

Specification of U.S. Pat. No. 6,834,005

[Non-Patent Reference 1]

A. Yamaguchi et al., “Real-Space Observation of Current-Driven Domain Wall Motion in Submicron Magnetic Wires”, Physical Review Letters, Vol. 92, No. 7, P. 077205-1 (2004)

However, in the technique proposed in Patent Reference 1, the recording layer in a U-shape or others is formed vertically to the substrate, which makes it difficult to form the recording layer. It is not easy either to form the restriction regions (pining sites) for restricting the motion of the domain walls in such recording layer. Furthermore, the technique proposed in Patent Reference 1, in which the recording layer is formed vertical to the substrate, has a very large number of fabrication steps, which makes it difficult to decrease the cost.

### SUMMARY OF THE INVENTION

An object of the present invention is to provide a magnetic memory device and a method for fabricating the magnetic memory device which facilitates the high integration.

According to one aspect of the present invention, there is provided a magnetic memory device comprising a recording layer formed linearly over a substrate, a plurality of pinning sites for restricting motion of domain walls being formed in the recording layer at a prescribed pitch, and regions between said plurality of pinning sites being a plurality of recording bits, the recording layer including a first recording layer portion and a second recording layer portion, the second recording layer portion being positioned above the first recording layer portion, and one end of the second recording layer portion being connected to one end of the first recording layer portion.

According to another aspect of the present invention, there is provided a magnetic memory device comprising a recording layer formed linearly over a substrate, a plurality of pinning sites for restricting motion of domain walls being formed in the recording layer at a prescribed pitch, and regions between said plurality of pinning sites being a plurality of recording bits, the recording layer including a first recording layer portion and a second recording layer portion arranged side by side with respect to a plane of the substrate, and one end of the first recording layer portion and one end of the second recording layer portion being connected to each other.

According to further another aspect of the present invention, there is provided a method for fabricating a magnetic memory device comprising the steps of: forming the first recording layer linearly over a substrate, pinning sites for restricting the motion of domain walls being formed in the first recording layer at a prescribed pitch; etching the region of the first recording layer except one end thereof to a prescribed thickness; forming an insulation layer burying the first recording layer; and forming the second recording layer linearly over the insulation layer in the region above the first recording layer, the second recording layer being connected to said one end of the first recording layer, and pinning sites for restricting motion of domain walls being formed in the second recording layer at said prescribed pitch.

According to further another aspect of the present invention, there is provided a method for fabricating a magnetic memory device comprising the step of forming a recording layer linearly over a substrate, pinning sites for restricting motion of domain walls being formed in the recording layer at a prescribed pitch, the recording layer including a first recording layer portion and a second recording layer portion arranged side by side with respect to a plane of the substrate, and one end of the first recording layer portion and one end of the second recording layer portion being connected to each other.

According to the present invention, the second recording layer portion is formed above the first recording layer portion, and the end of the second recording layer portion is connected to one end of the first recording layer portion, whereby the space required to form the recording layer can be small. Besides, such recording layer can be formed relatively easily. According to the present invention, the pinning sites for restricting the motion of the domain walls are easily formed in the recording layer by photolithography. Thus, the present invention can provides a magnetic memory device and a method for fabricating the magnetic memory device which can easily realize high integration.

According to the present invention, the first recording layer portion and the second recording layer portion are arranged side by side with respect to the plane of the substrate, and the end of the first recording layer portion and the end of the second recording layer portions are connected to each other, whereby the region required to form the recording layer can be short. Thus, the present invention can provide a magnetic memory device of high integration. The present invention can also increase the degree of freedom of the layout in designing.

### BRIEF DESCRIPTION OF THE DRAWINGS

FIG. 1 is a sectional view of the magnetic memory device according to a first embodiment of the present invention.

FIG. 2 is a perspective view of the recording layer of the magnetic memory device according to the first embodiment of the present invention.

FIG. 3 is a sectional view of the magnetic memory device according to the first embodiment of the present invention, which illustrates the operation principle thereof (Part 1).

FIG. 4 is a sectional view of the magnetic memory device according to the first embodiment of the present invention, which illustrates the operation principle thereof (Part 2).

FIGS. 5A to 5C are sectional views of the magnetic memory device according to the first embodiment of the present invention in the steps of the method for fabricating the magnetic memory device, which illustrate the method (Part 1).

FIGS. 6A and 6B are sectional views of the magnetic memory device according to the first embodiment of the present invention in the steps of the method for fabricating the magnetic memory device, which illustrate the method (Part 2).

FIGS. 7A and 7B are sectional views of the magnetic memory device according to the first embodiment of the present invention in the steps of the method for fabricating the magnetic memory device, which illustrate the method (Part 3).

FIGS. 8A and 8B are sectional views of the magnetic memory device according to the first embodiment of the present invention in the steps of the method for fabricating the magnetic memory device, which illustrate the method (Part 4).

FIGS. 9A and 9B are sectional views of the magnetic memory device according to the first embodiment of the present invention in the steps of the method for fabricating the magnetic memory device, which illustrate the method (Part 5).

FIGS. 10A and 10B are sectional views of the magnetic memory device according to the first embodiment of the present invention in the steps of the method for fabricating the magnetic memory device, which illustrate the method (Part 6).

FIGS. 11A and 11B are sectional views of the magnetic memory device according to the first embodiment of the present invention in the steps of the method for fabricating the magnetic memory device, which illustrate the method (Part 7).

FIGS. 12A and 12B are sectional views of the magnetic memory device according to the first embodiment of the present invention in the steps of the method for fabricating the magnetic memory device, which illustrate the method (Part 8).

FIGS. 13A and 13B are sectional views of the magnetic memory device according to the first embodiment of the present invention in the steps of the method for fabricating the magnetic memory device, which illustrate the method (Part 9).

FIG. 14 is a plan view of the recording layer of the magnetic memory device according to a second embodiment of the present invention.

FIG. 15 is a sectional view of the magnetic memory device of the magnetic memory device according to the second embodiment of the present invention.

FIGS. 16A to 16C are sectional views of the magnetic memory device according to the second embodiment of the present invention in the steps of the method for fabricating the magnetic memory device, which illustrate the method (Part 1).

FIGS. 17A and 17B are sectional views of the magnetic memory device according to the second embodiment of the present invention in the steps of the method for fabricating the magnetic memory device, which illustrate the method (Part 2).

FIGS. 18A and 18B are sectional views of the magnetic memory device according to the second embodiment of the present invention in the steps of the method for fabricating the magnetic memory device, which illustrate the method (Part 3).

FIG. 19 is a sectional view of the magnetic memory device according to the second embodiment of the present invention in the steps of the method for fabricating the magnetic memory device, which illustrates the method (Part 4).

### DETAILED DESCRIPTION OF THE INVENTION

### A First Embodiment

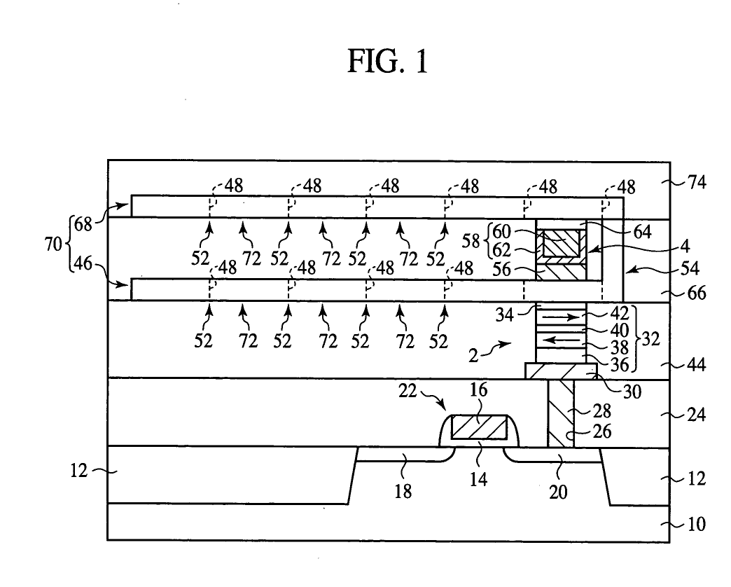

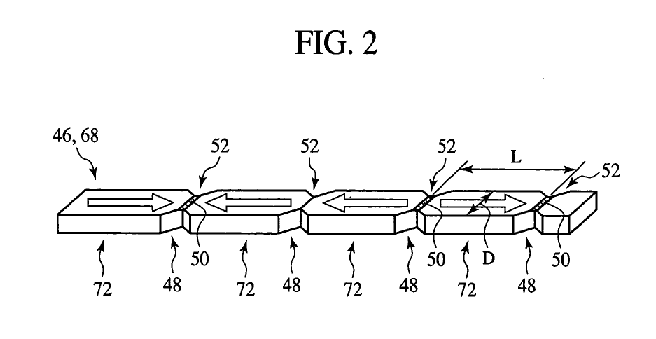

The magnetic memory device and the method for fabricating the memory device according to a first embodiment of the present invention will be explained with reference to FIGS. 1 to 13B. FIG. 1 is a sectional view of the magnetic memory device according to the present embodiment, which illustrates a structure thereof. FIG. 2 is a perspective view of the recording layers of the magnetic memory device according to the present embodiment. Hundreds to tens of thousands of recording bits can be formed in the recording layers of the magnetic memory device according to the present embodiment, but several recording bits are illustrated here.

(The Magnetic Memory Device)

First, the magnetic memory device according to the present embodiment will be explained with reference to FIGS. 1 and 2.

Device isolation regions 12 for defining device regions are formed on a silicon substrate 10.

On the silicon substrate 10 with the device isolation regions 12 formed on, gate electrodes 16 are formed with a gate insulation film 14 formed therebetween.

In each device region on both sides of each gate electrode 16, source/drain regions 18, 20 are respectively formed. Thus, in the device region, a transistor 22 including the gate electrode 16 and the source/drain regions 18, 20 is formed.

An inter-layer insulation film 24 is formed on the silicon substrate 10 with the transistor 22 formed on.

In the inter-layer insulation film 24, a contact hole 26 is formed down to the source/drain region 20.

In the contact hole 26, a contact plug 28 is buried, connected to the source/drain region 20.

On the inter-layer insulation film 24, a lower electrode layer 30 is formed, electrically connected to the source/drain region 20 via the contact plug 28.

On the lower electrode layer 30, a fixed magnetization layer 32 and a barrier layer (tunnel insulation film) 34 are formed. The fixed magnetization layer 32 is formed of the layer film of an anti-magnetic layer 36 of, e.g., IrMn or PtMn or others, a ferromagnetic layer 38 of, e.g., CoFe or others, a non-magnetic layer 40 of, e.g., Ru, Rh, Cr or others and a ferromagnetic layer 42 of, e.g., CoFe or others. The barrier film 34 is formed of, e.g., Al₂O₃.

On the inter-layer insulation film 24 with the lower electrode layer 30, the fixed magnetization layer 32 and the barrier layer 34 formed on, an inter-layer insulation film 44 is buried with the upper surface of the barrier layer 34 exposed.

On the inter-layer insulation film 44, a first linear (strip-shaped) magnetic layer (the first recording layer portion) 46 is formed. The width D of the first magnetic layer 46 (see FIG. 2) is, e.g., about 10-100 nm. The first magnetic layer 46 is formed of, e.g., CoFeB.

In the side walls of the first magnetic layer 46, notches 48 are formed at a prescribed pitch. The notches 48 are, e.g., wedge-shaped. The notches 48 are formed in both side walls of the first magnetic layer 46.

The first magnetic layer 46 has the sectional area decreased at the parts where the notches 48 are formed. The parts of the first magnetic layer 46 having the sectional area decreased are stable in terms of the energy in comparison with the parts of the first magnetic layer 46 having the larger sectional area. The parts of the first magnetic layer 46 having the sectional area decreased by the notches 48 can trap the domain walls 50 (see FIG. 2). Accordingly, the parts of the first magnetic layer 46, where the notches 48 are formed, can function as pinning sites 52 for restricting the motion of the domain walls 50.

The domain walls 50 trapped by the pinning sites 52 can be suitable moved by the spin torque generated when current is flowed in the longitudinal direction of the first magnetic layer 46.

The first magnetic layer 46 has on one end an upward projection 54. In other words, the first magnetic layer 46 has a larger thickness at said one end than in the rest region. Said one end of the first magnetic layer 46 is projected upward so as to ensure the connection between the first magnetic layer 46 and the second magnetic layer 68.

On the first magnetic layer 46 near one end thereof, a non-magnetic metal layer 56 is formed. The non-magnetic metal layer 56 is for separating the recording layer 46 and an interconnection 58 which will be described later while connecting the interconnection 58 and the recording layer 46 with each other.

The interconnection 58 for both write and read is formed on the non-magnetic metal layer 56. The interconnection 58 is formed of a non-magnetic metal layer 60 and a ferromagnetic metal layer 62. The ferromagnetic metal layer 62 is formed, covering the surfaces of the non-magnetic metal layer 60 except the surface opposed to a second magnetic layer 68. Such structure of the interconnection 58 is called the clad structure. The interconnection 58 of the clad structure having the periphery of the non-magnetic metal layer 60 shielded by the ferromagnetic metal layer 62 can concentrate the magnetic flux on the side of the second magnetic layer 68.

An insulation film 64 of, e.g., silicon oxide film is formed on the interconnection 58. The insulation film 64 is for separating the interconnection 58 and the second magnetic layer 68 from each other.

On the inter-layer insulation film 44 with the first magnetic layer 46, etc., an inter-layer insulation film 66 is buried with the surface of the projection 54 of the first magnetic layer 46 exposed.

On the inter-layer insulation film 66, a second linear (strip-shaped) magnetic layer (the second recording layer portion) 68 is formed. The width D of the second magnetic layer 68 (see FIG. 2) is, e.g., about 10-100 nm, which is the same as the width of the first magnetic layer 46. The second magnetic layer 68 is formed of, e.g. CoFeB, as is the first magnetic layer.

In the side walls of the second magnetic layer 68, notches 48 are formed at a prescribed pitch. The notches 48 are, e.g., wedge-shaped. The notches 48 are formed in both side walls of the second magnetic layer 68.

The second magnetic layer 68 has the sectional area decreased at the parts where the notches 48 are formed. The parts of the second magnetic layer 68 having the sectional area decreased are stable in terms of the energy in comparison with the parts of the second magnetic layer 68 having the larger sectional area. The parts of the second magnetic layer 68 having the sectional area decreased by the notches 48 can trap the domain walls 50 (see FIG. 2). Accordingly, the parts of the second magnetic layer 68, where the notches 48 are formed, can function as pinning sites 52 for restricting the motion of the domain walls 50.

The domain walls 50 trapped by the pinning sites 52 can be suitably moved by the spin torque generated when current is flowed in the longitudinal direction of the second magnetic layer 68.

The second magnetic layer 68 is connected to the first magnetic layer 46 at the projection 54 of the first magnetic layer 46. That is, the second magnetic layer 68 is serially connected to the first magnetic layer 46. The first magnetic layer 46 and the second magnetic layer 68 form a recording layer 70.

The recording layer 70 is folded back at the middle. In other words, the first recording layer portion 46 and the second recording layer portion 68 have lengths which are substantially equal to each other. The second recording layer portion 68 is positioned above the first recording layer portion 46.

In the present embodiment, the second recording layer portion 68 is formed above the first recording layer portion 46, and the end of the second recording layer portion 68 and the end of the first recording layer portion 46 are connected to each other, which allows the space required to form the recording layer 70 to be small. That is, according to the present embodiment, the magnetic memory device can have high integration.

The domain walls 50 trapped by the pinning sites 52 can be suitably moved by the spin torque generated when current is flowed in the longitudinal direction of the recording layer 70.

The regions between the pinning sites 52 are recording bits 72. That is, the respective recording bits 72 of the recording layer 70 are defined by the pinning sites 52. Accordingly, the length L of one recording bit 72 is equal to the pitch L between the pinning sites 52.

The lower electrode 30, the fixed magnetization layer 32, the barrier layer 34, the non-magnetic metal layer 56, the interconnection (upper electrode) 58, etc. form a reading element (reader) 2 of the magnetoresistance effect element for reading information recorded in the recording bits 72 of the recording layer 70.

The reading element 2 is located near the part where the recording layer 70 is folded back. In other words, the reading element 2 is located near the part which is substantially a half of the total length of the recording layer 70. The reason why, in the present embodiment, the reading element 2 is located near the part where the recording layer 70 is folded back will be described later.

The interconnection 58 of the clad structure forms a writing element (writer) 4 for writing information in the recording bits 72 of the recording layer 70.

The writing element 4 is located near the part where the recording layer 70 is folded back. In other words, the writing element 4 is located near the part which is substantially a half of the total length of the recording layer 70. The reason why, in the present embodiment, the writing element 4 is located near the part where the recording layer 70 is folded back will be described later.

On the inter-layer insulation film 66 with the second magnetic layer 68 formed on, an inter-layer insulation film 74 is formed, burying the second magnetic layer 68.

Thus, the magnetic memory device according to the present embodiment is constituted.

(The Operation Principle)

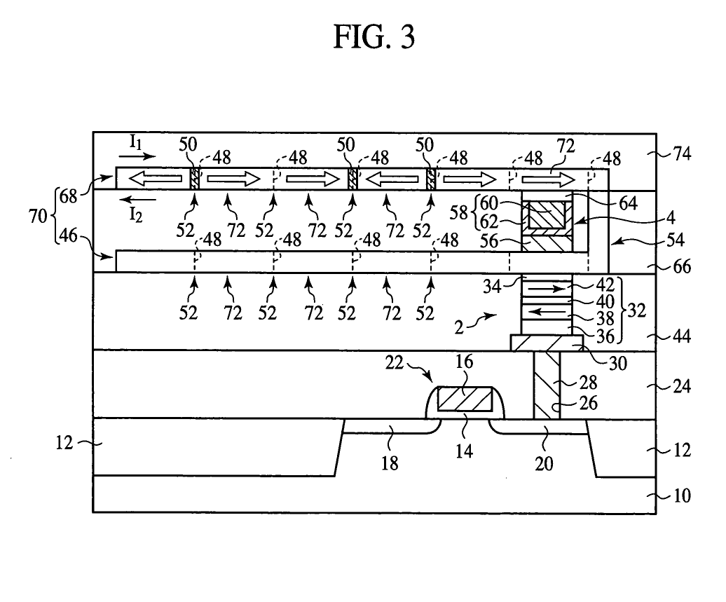

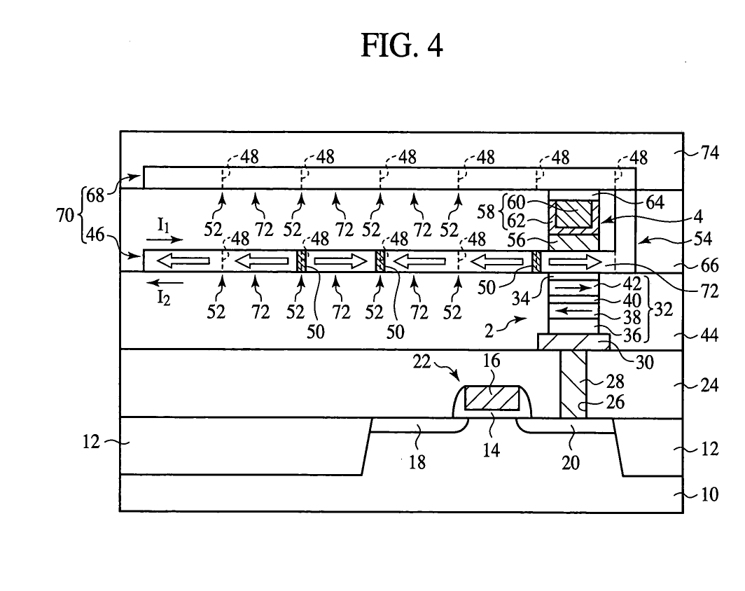

Next, the operation principle of the magnetic memory device according to the present embodiment will be explained with reference to FIGS. 3 and 4. FIG. 3 is a sectional view (Part 1) of the magnetic memory device according to the present embodiment, which illustrates the operation principle. FIG. 4 is a sectional view (Part 2) of the magnetic memory device according to the present embodiment, which illustrates the operation principle.

First, the method for writing information in the recording bits 34 of the recording layer 22 will be explained with reference to FIG. 3. The directions indicated by the thick arrows in FIG. 3 are magnetization directions.

Information is written in the recording bits 72 of the recording layer 70 by flowing a write current to the interconnection 58. The direction of the write current to be flown to the interconnection 58 is suitably set, whereby the magnetization direction in the recording bits 72 can be set in a required direction.

When the magnetization directions of the recording bits 72 adjacent to each other are opposite, the domain wall 50 is present between these recording bits 72. On the other hand, when the magnetization directions of the recording bits 72 adjacent to each other are the same, the domain wall 50 is absent between these recording bits 72. The magnetization directions being opposite to each other with respect to the domain wall 50 is a general property of the ferromagnet.

In the magnetic memory device according to the present embodiment, the domain walls 50 can be suitably moved by the spin torque generated when the currents are flown in the longitudinal direction of the recording layer 70, whereby the information written in the recording bits 72 can be suitably moved. The writing element 4 directly writes information into only one recording bit 72, but the information written in the recording bit 72 can be shifted by moving the domain walls 50, whereby information can be written in the respective recording bits 72.

That is, when the current is flown in the longitudinal direction of the recording layer 70, the domain walls 50 are moved in the direction of flow of electron spins. For example, when the current is flown in the direction I₁ in FIG. 3, the electron spins flow in the direction opposite to the flow direction of the current, and the domain walls 50 are moved in the direction opposite to the flow direction of the current. As the domain walls 50 are moved, the magnetic domains defined by the domain walls 50 are moved. In other words, as the domain walls 50 are moved, the information written in the recording bits 72 is moved. Information is written in the recording bit 72 while the information written in the recording bits 72 is being moved, whereby the information can be written in the respective recording bits 72.

In the case that the writing element 4 is disposed near the end of the recording layer 70, when information written in the recording bits 72 is suitably moved to write information in the recording bit 72 opposed to the writing element 4, the electron spins often move beyond the end. In such case, part of the information written in the respective recording bits 72 of the recording layer 70 is erased. In the present embodiment, the writing element 4 is located near the part where the recording layer 70 is folded back.

Then, the method for reading information written in the recording bits 34 of the recording layer 22 will be explained with reference to FIG. 4.

As illustrated in FIG. 4, when the magnetization direction of the fixed magnetization layer 42 is the same as (parallel with) the magnetization direction of the recording bits 72 opposed to the fixed magnetization layer 42, a low-resistance state is present between the lower electrode layer 30 and the interconnection 58.

On the other hand, when the magnetization direction of the fixed magnetization layer 42 and the magnetization direction of the recording bit 72 opposed to the fixed magnetization layer 42 are opposite to (anti-parallel with) each other, a high resistance state is present between the lower electrode layer 30 and the interconnection 58.

The two states of the high resistance state and the low resistance state are related to data “0” or data “1”. The two states of the high resistance state and the low resistance states are related to data “0” or data “1”, whereby information written in the recording bits 34 of the recording layer 70 can be judged.

For example, information written in the recording bits 34 can be judged by connecting the interconnection 58 to a prescribed potential and observing the potential of the lower electrode layer 30 when the transistor 22 is on.

In the case that the reading element 2 is disposed near the end of the recording layer 70, when information written in the recording bits 72 is suitably moved to read information in the recording bit 72 opposed to the reading element 2, the electron spins often move beyond the end. In such case, part of the information written in the respective recording bits 72 of the recording layer 70 is erased. In the present embodiment, the reading element 2 is located near the part where the recording layer 70 is folded back.

As described above, according to the present embodiment, the second recording layer portion 68 is formed, positioned above the first recording layer portion 46, and the end of the second recording layer portion 68 and the end of the first recording layer portion 46 are connected to each other, whereby the space for the recording layer 70 formed in can be small. Besides, such recording layer 70 can be formed relatively easily. In such recording layer 70, the pinning sites for restricting the motion of the domain walls can be easily formed by photolithography. Thus, the magnetic memory device according to the present invention can easily realize high integration.

(The Method for Fabricating the Magnetic Memory Device)

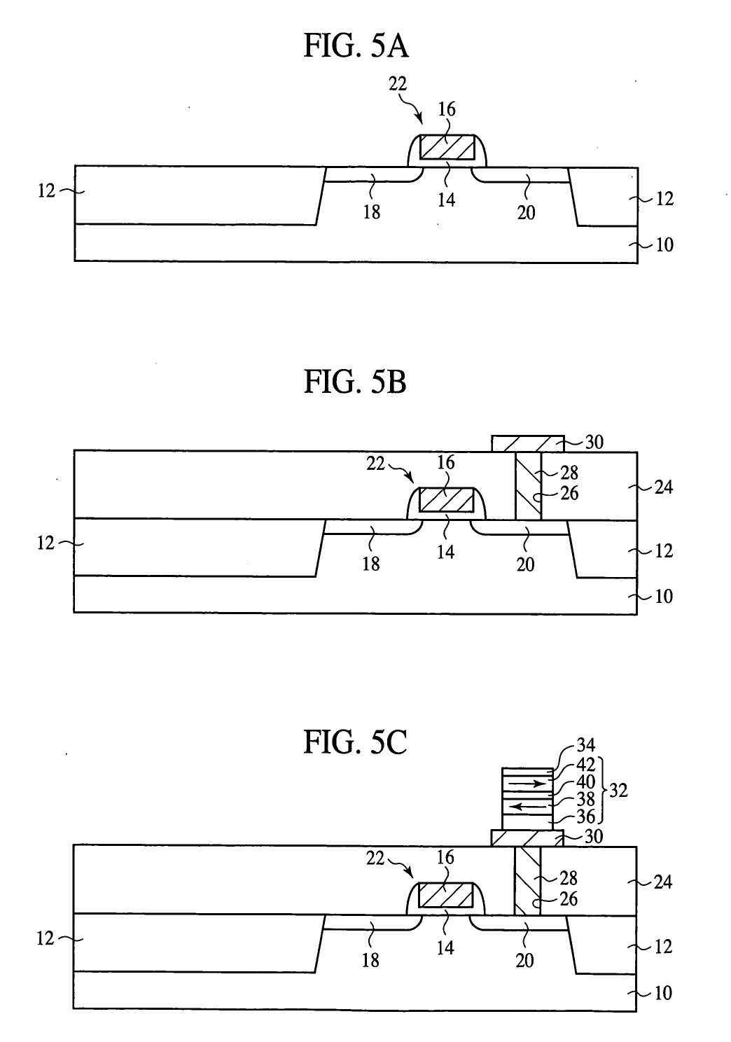

Then, the method for fabricating the magnetic memory device according to the present embodiment will be explained with reference to FIGS. 5A to 13B. FIGS. 5A to 13B are sectional views of the magnetic memory device according to the present embodiment in the steps of the method for fabricating the magnetic memory device, which illustrate the method.

First, the device isolation regions 12 for defining the device regions are formed on the silicon substrate 10 by, e.g., STI (Shallow Trench Isolation).

Next, in each device region defined by the device isolation regions 12, the transistor 22 including the gate electrode 16 and the source/drain regions 18, 20 is formed in the same forming process as the usual MOS transistor (see FIG. 5A).

Next, the silicon oxide film 24 is formed by, e.g., CVD on the silicon substrate 10 with the transistor 22, etc. formed on.

Then, the surface of the silicon oxide film 24 is planarized by, e.g., CMP. Thus, the inter-layer insulation film 24 of silicon oxide film is formed.

Next, the contact hole 26 is formed in the inter-layer insulation film 24 down to the source/drain region 20 by photolithography.

Next, a barrier metal film of titanium nitride is formed by, e.g., CVD.

Next, a tungsten film is formed by, e.g., CVD.

Next, the tungsten film and the barrier metal film are polished by, e.g., CMP until the surface of the inter-layer insulation film 24 is exposed. Thus, the contact plug 28 is buried in the contact hole 26.

Then, a 5-50 nm-thickness Ta film 30 is formed on the entire surface by, e.g., sputtering. The Ta film 30 is to be the lower electrode layer.

Next, the Ta film 30 is patterned by photolithography. Thus, the lower electrode layer 30 of Ta is formed (see FIG. 5B).

Then, the anti-ferromagnetic layer 36 of IrMn or PtMn is formed on the entire surface by, e.g., sputtering. The thickness of the anti-ferromagnetic layer 36 is, e.g., 5-20 nm.

Then, the ferromagnetic layer 38 of a 1-5 nm-thickness CoFe film is formed on the entire surface by, e.g., sputtering.

Next, the non-magnetic layer 40 of a 0.2-1.5 nm-thickness Ru film is formed on the entire surface by, e.g., sputtering.

Next, the non-magnetic layer 42 of a 1-5 nm-thickness CoFe film is formed on the entire surface by, e.g., sputtering.

Next, the barrier layer (tunnel insulation film) 34 of a 0.4-2 nm-thickness Al₂O₃ film is formed on the entire surface by, e.g., sputtering.

Then, a photoresist film (not illustrated) is formed by, e.g., spin coating.

Next, the barrier layer 34, the ferromagnetic layer 42, the non-magnetic layer 40, the ferromagnetic layer 38 and the anti-ferromagnetic layer 36 are patterned by photolithography. Thus, the fixed magnetization layer 32 is formed of the ferromagnetic layer 42, the non-magnetic layer 40, the ferromagnetic layer 38 and the anti-ferromagnetic layer 36 (see FIG. 5C).

Next, the silicon oxide film 44 is formed by, e.g., CVD on the inter-layer insulation film 24 with the lower electrode layer 30, the fixed magnetization layer 32 and the barrier layer 34 formed on.

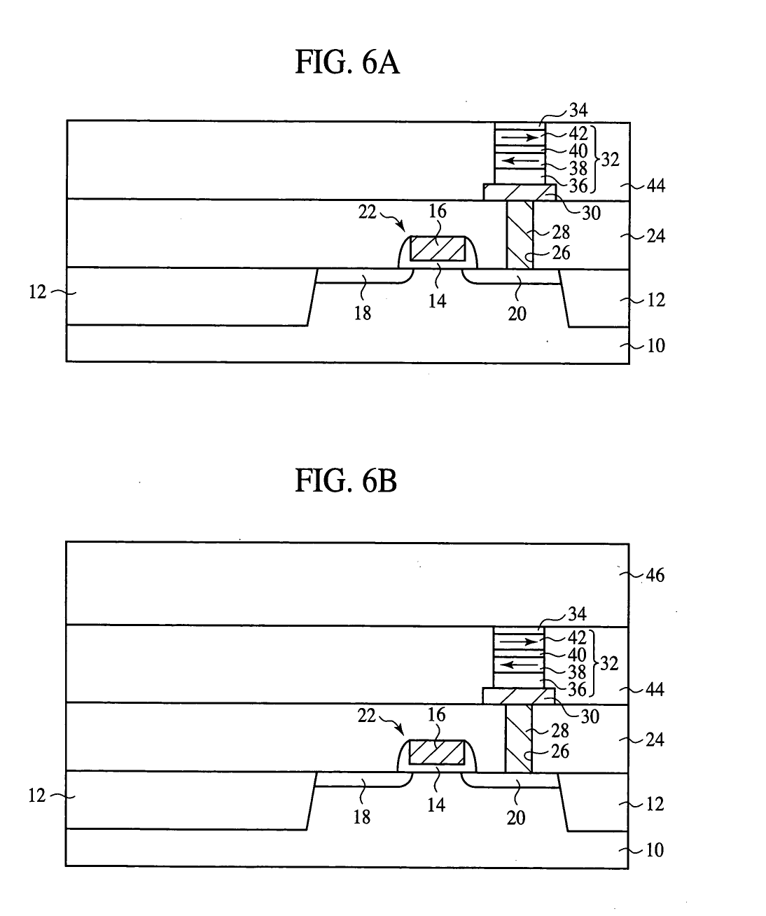

Next, the surface of the silicon oxide film 44 is polished by, e.g., CMP until the surface of the barrier layer 34 is exposed. Thus, the inter-layer insulation film 44 of silicon oxide film is formed (see FIG. 6A).

Next, the CoFeB film 46 is formed on the entire surface by, e.g., sputtering. The film thickness of the CoFeB film 46 is, e.g., 10-100 nm. The CoFeB film 46 is for forming the first magnetic layer (the first recording layer portion) 46 (see FIG. 1) (see FIG. 6B).

Then, a photoresist film 76 is formed by, e.g., spin coating.

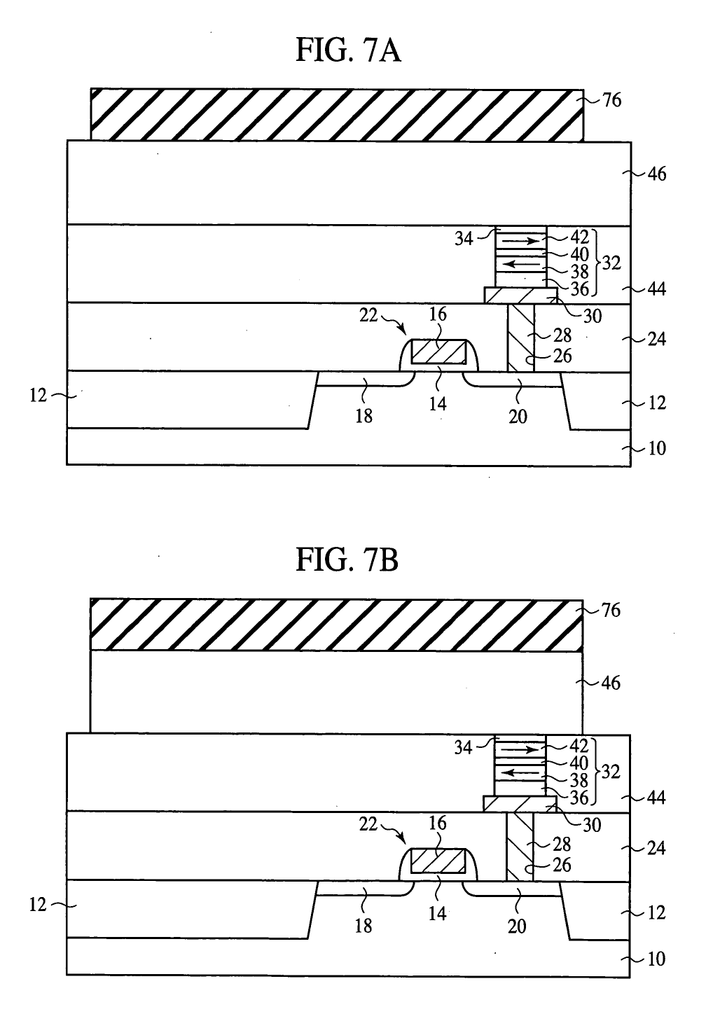

Then, the photoresist film 76 is patterned into the plane shape of the first magnetic layer 46 by photolithography (see FIG. 7A). In forming the pinning sites 52 for restricting the motion of the domain walls 50 are formed by the notches 48, notches are formed in the photoresist film 76.

Next, with the photoresist film 76 as the mask, the CoFeB film 46 is patterned by ion milling or RIE (Reactive Ion Etching) (see FIG. 7B). Then, the photoreisst film 76 is released.

Next, a photoresist film 78 is formed by, e.g., spin coating.

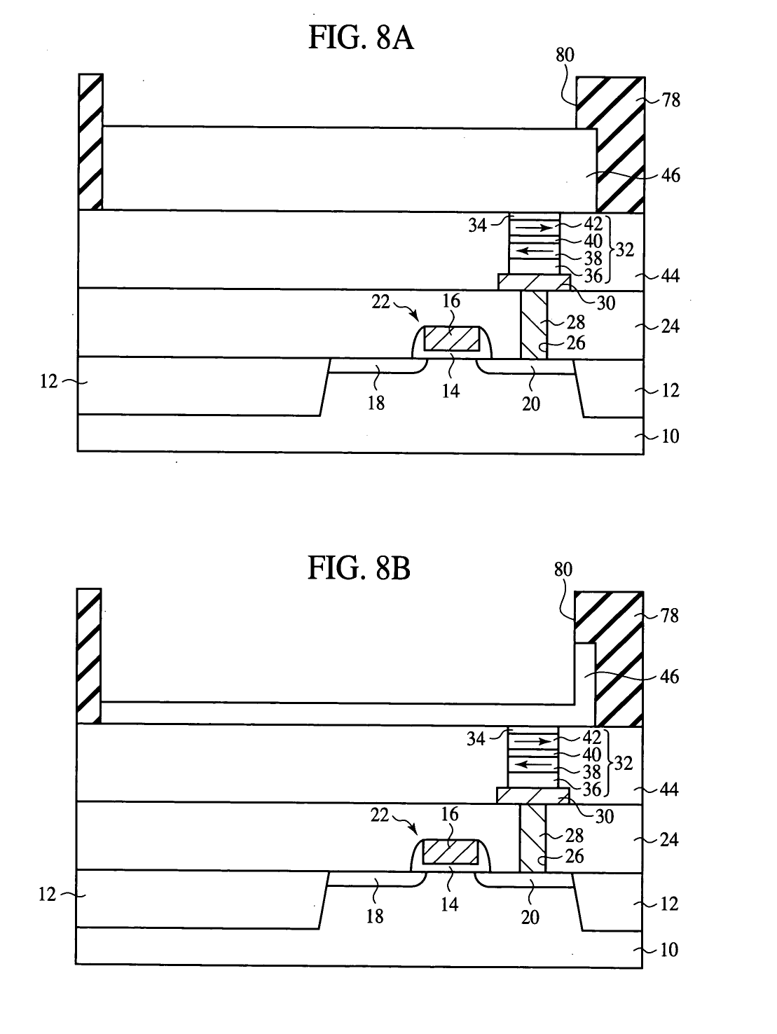

Next, the photoresist film 78 is patterned by photolithography. Specifically, an opening 80 is formed in the photoresist film 78, covering one end of the CoFeB film 46 to be the first magnetic layer and covering the region except the region where the CoFeB film 46 is formed (see FIG. 8A).

Then, with the photoresist film 78 as the mask, the CoFeB film 46 is etched by ion milling or RIE. At this time, the CoFeB film 46 is etched until the thickness of the CoFeB film 46 in the region other than one end thereof becomes a prescribed thickness. Thus, the first magnetic layer (the first recording layer portion) 46 of CoFeB is formed (see FIG. 8B).

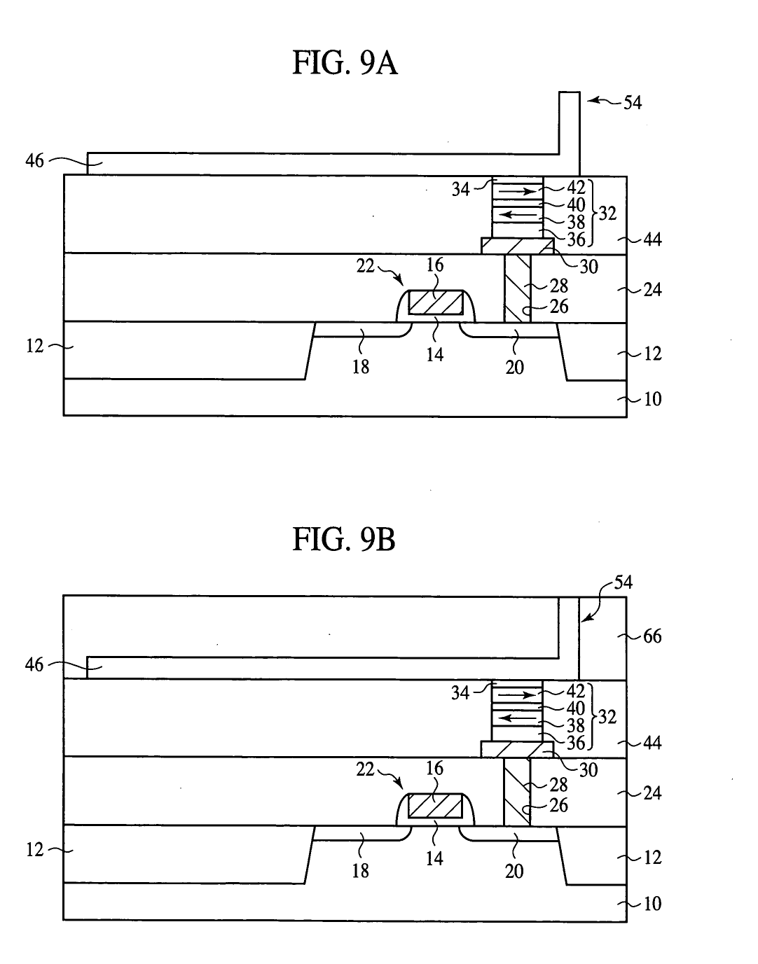

Then, the photoresist film 78 is released (see FIG. 9A).

Next, the silicon oxide film 66 is formed by, e.g., CVD on the inter-layer insulation film 44 with the first magnetic layer 46 formed on.

Next, the surface of the silicon oxide film 66 is polished by, e.g., CMP until the surface of the projection 54 of the first magnetic layer 46 is exposed. Thus, the inter-layer insulation film 66 of silicon oxide film is formed (see FIG. 9B).

Next, a photoresist film 82 is formed by, e.g., spin coating.

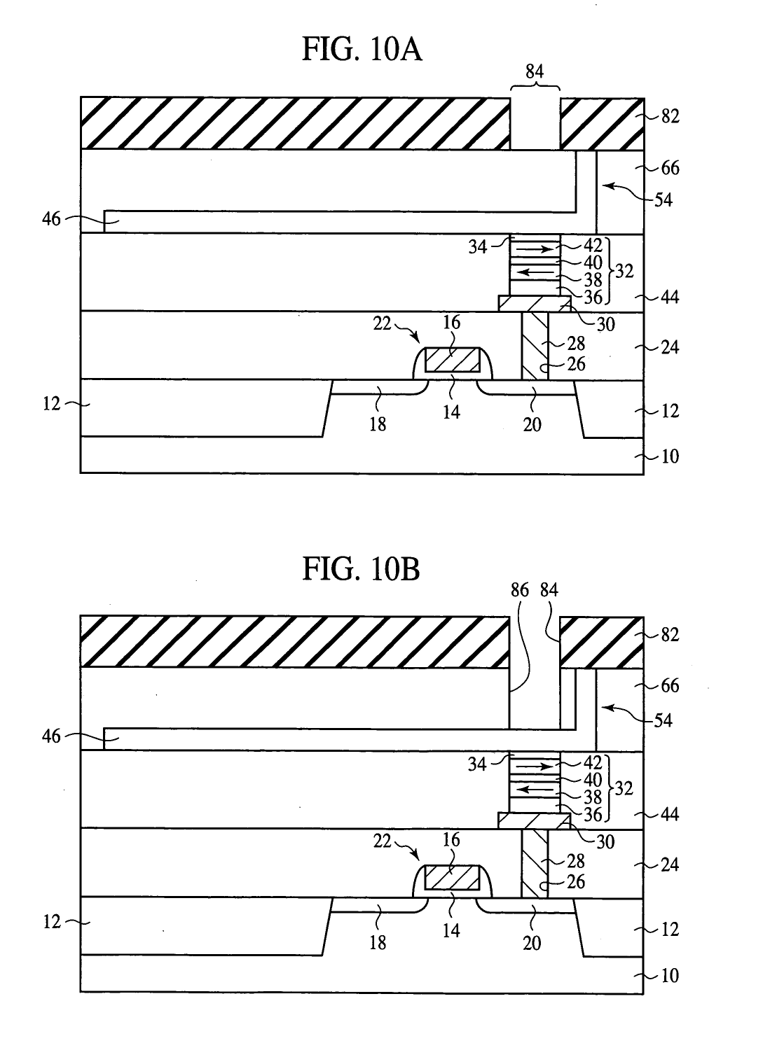

Next, the opening 84 is formed in the photoresist film 82 by photolithography (see FIG. 10A). The opening 84 is for forming the trench 86 in the inter-layer insulation film 66.

Next, with the photoresist film 82 as the mask, the inter-layer insulation film 66 is etched to form the trench 86 in the inter-layer insulation film 66 down to the first magnetic layer 46 (see FIG. 10B).

Next, the non-magnetic metal layer 56 is formed on the bottom of the trench 86 b, e.g., sputtering.

Then, the ferromagnetic metal layer 62 is formed by, e.g., sputtering in the groove 86 with the non-magnetic metal layer 56 formed in. The ferromagnetic metal layer 62 is formed, covering the upper surface of the non-magnetic metal layer 56 and the side wall of the trench 86. The ferromagnetic metal layer 62 can be formed, covering the upper surface of the non-magnetic metal layer 56 and the side wall of the trench 86 by suitably setting the incident angle of sputtered atoms corresponding to the depth of the trench 86.

Next, in the trench 86 with the non-magnetic metal layer 56 and the ferromagnetic metal layer 62 formed in, the non-magnetic metal layer 60 is formed by, e.g., sputtering.

Thus, the interconnection 58 of the clad structure including the non-magnetic metal layer 60 and the ferromagnetic metal layer 62 is buried in the trench 58.

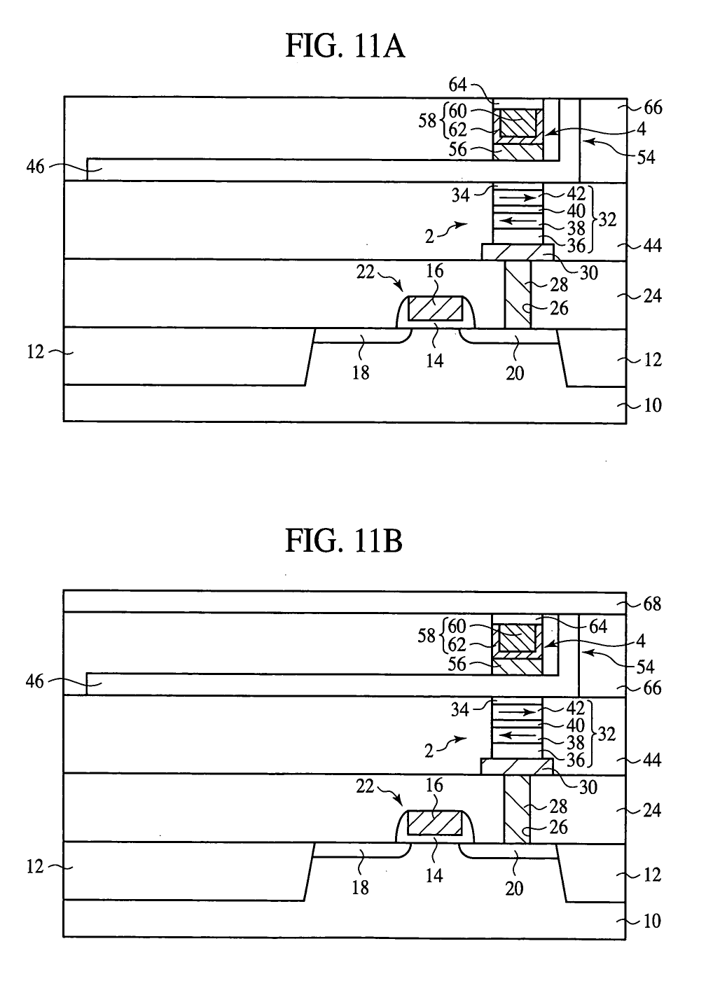

Then, the insulation film 64 of, e.g., silicon oxide film is formed by, e.g., sputtering or CVD in the trench 58 with the interconnection 58 formed in (see FIG. 11A).

Next, the CoFeB film 68 is formed on the entire surface by, e.g., sputtering (see FIG. 11B). The film thickness of the CoFeB film 68 is, e.g., 10-100 nm. The CoFeB film 68 is for forming the second magnetic layer (the second recording layer portion).

Next, a photoresist film 88 is formed by, e.g., spin coating.

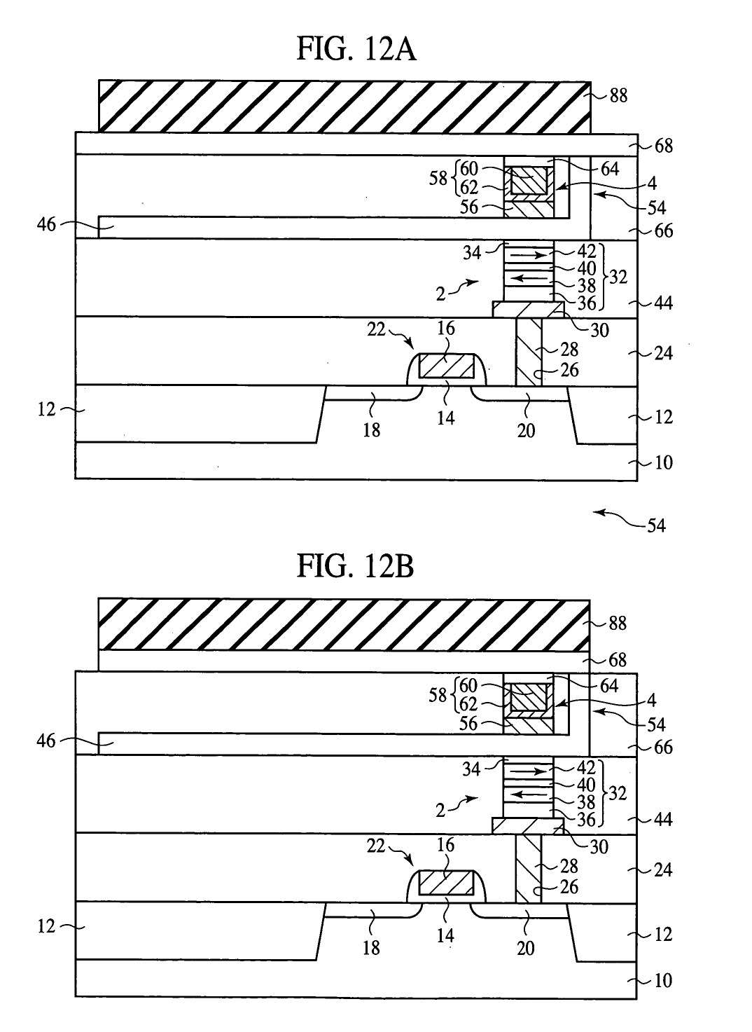

Next, the photoresist film 88 is patterned into the plane shape of the second magnetic layer 68 by photolithography (see FIG. 12A).

Then with the photoresist film 88 as the mask, the CoFeB film 68 is patterned by ion milling or RIE (Reactive Ion Etching). Thus, the second magnetic layer (the second recording layer portion) 68 of CoFeB is formed. The first magnetic layer 46 and the second magnetic layer 68 form the recording layer 70 (see FIG. 12B).

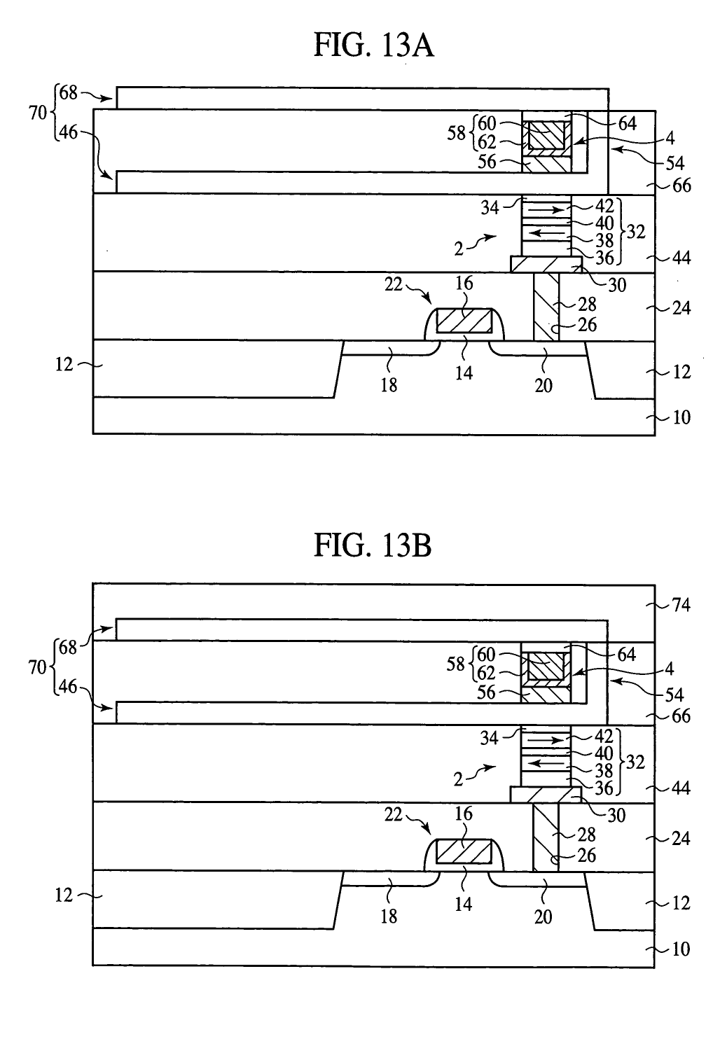

Next, the potoresist film 88 is released (see FIG. 13A).

Next, the interlayer insulation film 74 of silicon oxide film is formed on the entire surface by, e.g., CVD.

Thus, the magnetic memory device according to the present embodiment is fabricated (see FIG. 13B).

As described above, according to the present embodiment, the second recording layer portion 68 and the first recording layer portion 46 are formed with the former positioned above the latter and with the end of the former and the end of the latter connected to each other, whereby the space required to form the recording layer 70 can be small. Besides, the recording layer 70 can be easily formed.

According to the present embodiment, when the first recording layer portion 46 and the second recording layer portion 68 are patterned by photolithography, the pinning sites for restricting the motion of the domain walls can be formed, whereby the pinning sites can be easily formed.

Thus, according to the present embodiment, the magnetic memory device which can realize high integration can be easily fabricated by simple steps.

### A Second Embodiment

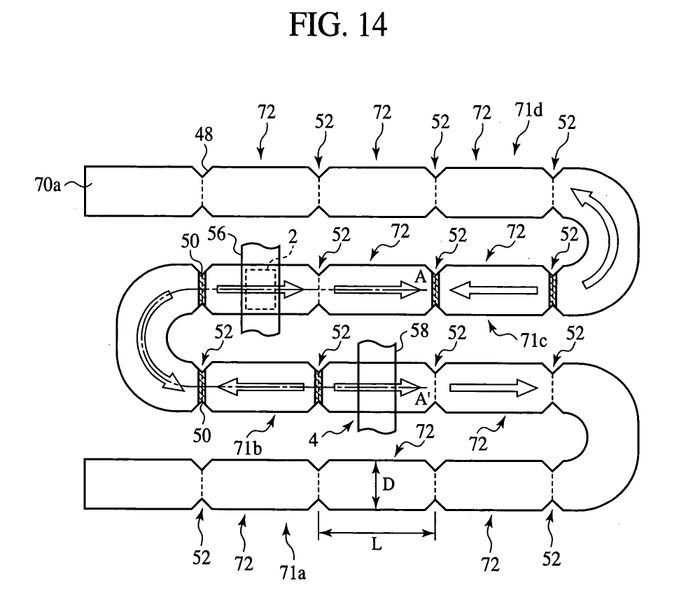

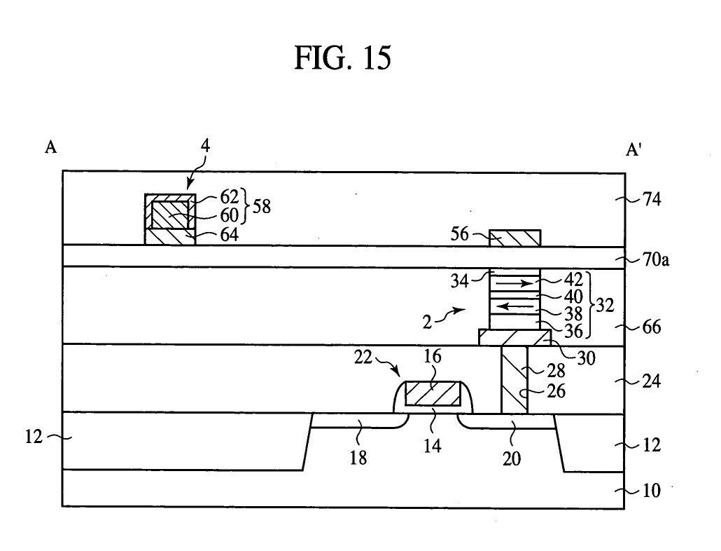

The magnetic memory device and the method for fabricating the magnetic memory device according to a second embodiment of the present invention will be explained with reference to FIGS. 14 to 19. FIG. 14 is a plan view illustrating the recording layer of the magnetic memory device according to the present embodiment. FIG. 15 is a sectional view of the magnetic memory device according to the present embodiment. Hundreds to tens of thousands of recording bits can be formed in the recording layers of the magnetic memory device according to the present embodiment, but several recording bits are illustrated here. The same members of the present embodiment as those of the magnetic memory device and the method for fabricating the magnetic memory device according to the first embodiment illustrated in FIGS. 1 to 13B are represented by the same reference numbers not to repeat or to simplify their explanation.

(The Magnetic Memory Device)

The magnetic memory device according to the present embodiment is characterized mainly in that a recording layer 70a is cyclically wound.

As illustrated in FIG. 14, in the magnetic memory device according to the present embodiment, the recording layer 70a is cyclically wound. In other words, the recording layer 70a includes a plurality of recording layer portions 71a-71d which are arranged side by side in plane of a substrate 10, and one end of the recording layer portion 71a is connected to one end of the recording layer portion 71b, the other end of the recording layer portion 71b is connected to one end of the recording layer portion 71c, the other end of the recording layer portion 71c is connected to one end of the recording layer portion 71d. The recording layer 70a is formed of, e.g., CoFeB, which is ferromagnet. The thickness of the recording layer 22a is, e.g., 10-100 nm. The recording layer 70a is wound in the present embodiment, so that the region required to form the recording layer 70a has a short length to improve the integration and the degree of freedom in designing.

The width D of the recording layer 70a, i.e., the width D of the recording bits 72 is, e.g., about 10-100 nm.

Pinning sites 52 for restricting the motion of the domain walls 50 are formed in the side wall of the recording layer 70a. The domain walls 50 trapped by the pinning sites 52 can be suitably moved by the spin torque generated when current is flown in the recording layer 70a.

The respective recording bits 72 of the recording layer 70a are defined by the spinning sites 52. That is, the regions between the pinning sites 52 are recording bits 72. Accordingly, the length L of one recording bit 72 is equal to the pitch of the pinning sites 52. The pitch L of the pinning sites 52, i.e., the length L of 1 recording bit 72 is, e.g., about 10-100 nm.

A reading element 2 is buried in the inter-layer insulation film 66 below the recording layer 70a.

On the inter-layer insulation film 66 with the recording layer 70a formed on, an inter-layer insulation film (not illustrated) is formed, burying the recording layer 70a.

On the recording layer 70a with the inter-layer insulation film (not illustrated) formed on, a non-magnetic metal layer 56 is formed. The non-magnetic metal layer 56 functions as the upper electrode layer of a reading element 2.

On the recording layer 70a with the inter-layer insulation film (not illustrated) buried in, an interconnection 58 for writing is formed with an insulation film 64 therebetween. The interconnection 58 is formed of a non-magnetic metal layer 60 and a ferromagnetic metal layer 62. The ferromagnetic metal layer 62 is formed, covering the surface of the non-magnetic metal layer 60 except the surface thereof opposed to the recording layer 70a. The interconnection 58 of such clad structure having the periphery of the non-magnetic metal layer 60 shielded by the ferromagnetic metal layer 62 can concentrate the magnetic flux on the side of the recording layer 70a.

Thus, the writing element 4 of the interconnection 58, etc. is formed.

An inter-layer insulation film 74 is formed on the inter-layer insulation film (not illustrated) with the non-magnetic metal layer 56, the interconnection 58, etc. formed on.

Thus, the magnetic memory device according to the present embodiment is constituted.

According to the present embodiment, a plurality of recording layer portions 71a-71d arranged side by side with respect to the plane of the substrate 10, and one end of the recording layer portion 71a is connected to one end of the recording layer portion 71b, the other end of the recording layer portion 71b is connected to one end of the recording layer portion 71c, the other end of the recording layer portion 71c is connected to one end of the recoding layer portion 71d, whereby the length of the region required to form the recording layer 22a can be small. Thus, according to the present embodiment, the magnetic memory can have high integration degree. The degree of freedom of the layout in designing can be increased.

(The Method for Fabricating the Magnetic Memory Device)

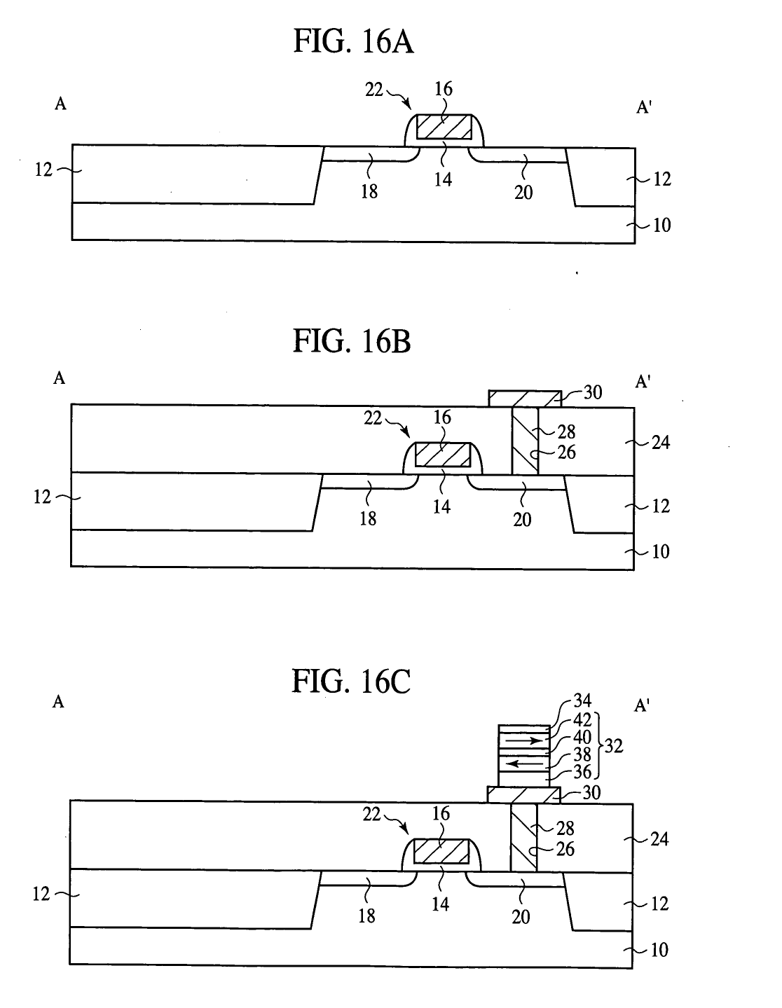

The method for fabricating the magnetic memory device according to the present embodiment will be explained with reference to FIGS. 16A to 19. FIGS. 16A to 19 are sectional views of the magnetic memory device according to the present embodiment in the steps of the method for fabricating the magnetic memory device.

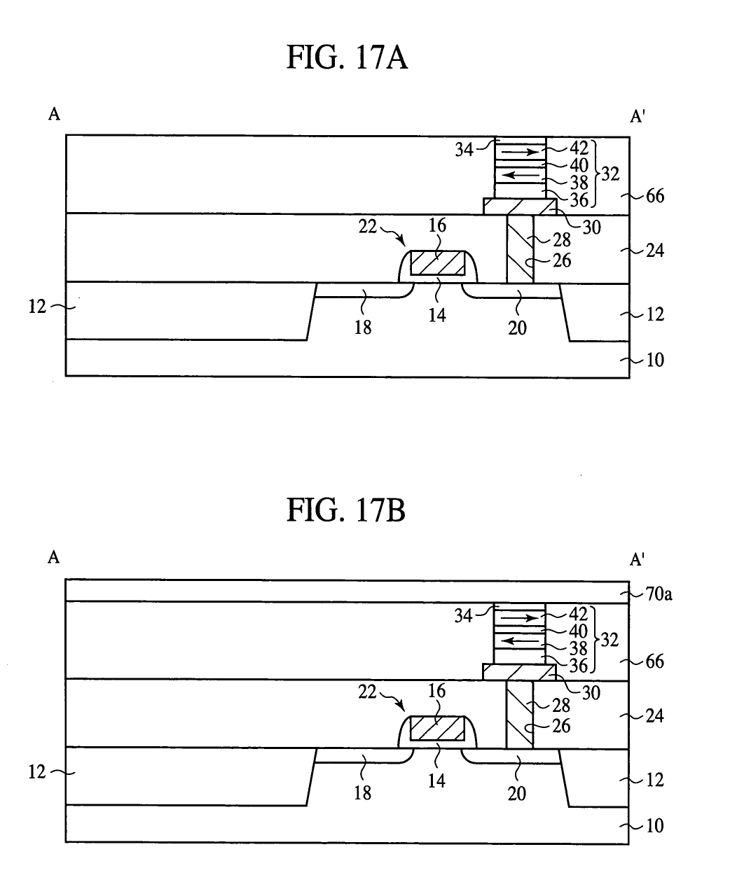

First, the step of forming the device isolation region 12 up to the step of planarizing the surface of the inter-layer insulation film 44 including this step are the same as in the magnetic memory device fabricating method according to the first embodiment described in FIGS. 5A to 6A, and their explanation will be omitted (see FIGS. 16A to 17A).

Next, the 10-100 nm-thickness CoFeB film 70a is formed on the entire surface by, e.g., sputtering. The CoFeB film 70a is to be the recording layer.

Next, a photoresist film (not illustrated) is formed by, e.g., spin coating.

Then, the photoresist film is patterned into the plane shape of the recording layer 70a by photolithography. That is, the photoresist film is patterned into the wound plane shape. In the case that the pinning sites 52 for restricting the motion of the domain walls 50 are formed by the notches 48, notches are formed in the photoresist film.

Then, with the photoresist film as the mask, the CoFeB film 70a is patterned by ion milling or RIE (Reactive Ion Etching). Then, the photoresist film is released (see FIG. 17B). Thus, the recording layer 70a of CoFeB is formed.

Next, a silicon oxide film is formed on the entire surface by, e.g., CVD.

Next, the silicon oxide film is polished by, e.g., CMP until the surface of the recording layer 70a is exposed.

Next the non-magnetic metal layer 56 is formed on the entire surface by, e.g., sputtering.

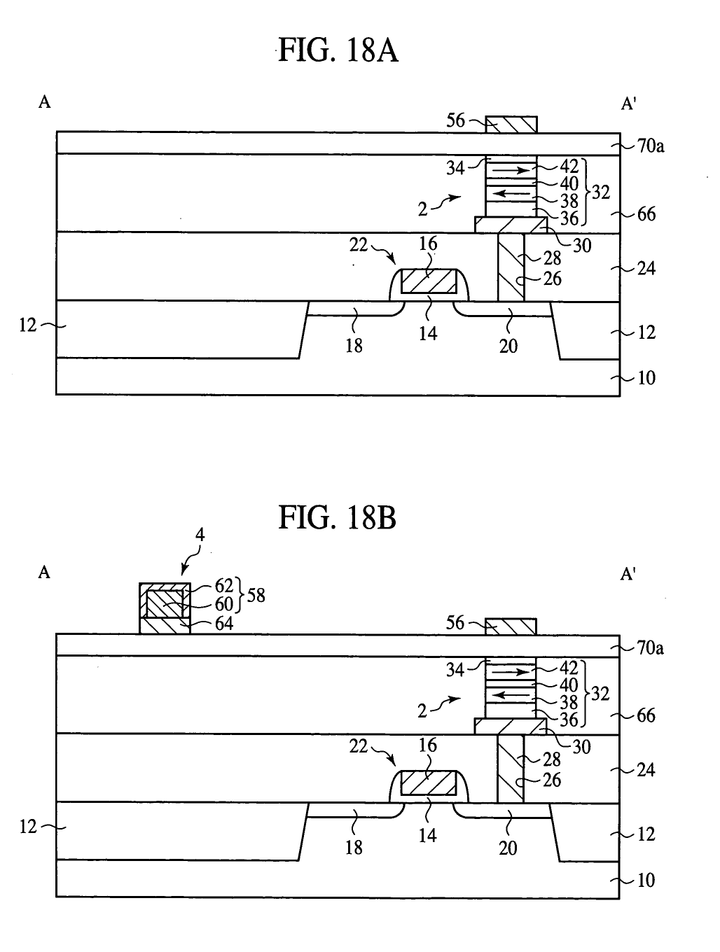

Next, the non-magnetic metal layer 56 is patterned by photolithography. Thus, the upper electrode 56 of the non-magnetic metal layer is formed (see FIG. 18A).

Next, the silicon oxide film 64 is formed on the entire surface by, e.g., CVD.

Next, the non-magnetic metal film 60 is formed on the entire surface by, e.g., sputtering.

Next, the non-magnetic metal layer 60 is patterned into the prescribed configuration by photolithography.

Next, the ferromagnetic metal layer 62 is formed on the entire surface by, e.g., sputtering.

Next, the ferromagnetic metal layer 62 is patterned by photolithography. Thus, the ferromagnetic metal layer 62 is formed on the upper surface and the side wall of the non-magnetic metal layer 60.

Thus, the interconnection 58 of the non-magnetic metal layer 60 and the ferromagnetic metal layer 62 is formed on the silicon oxide film 64 (see FIG. 18B).

Next, the inter-layer insulation film 74 of silicon oxide film is formed on the entire surface by, e.g., CVD.

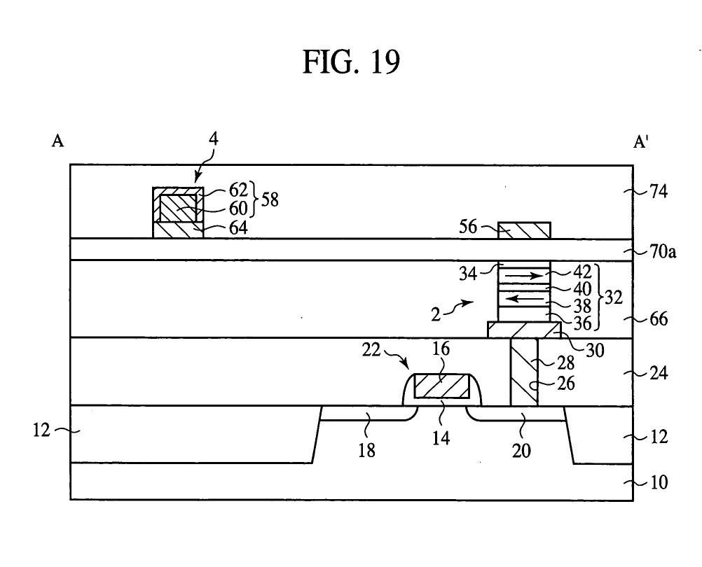

Thus, the magnetic memory device according to the present embodiment is fabricated (see FIG. 19).

### Modified Embodiments

The present invention is not limited to the above-described embodiments and can cover other various modifications.

For example, in the above-described embodiments, the ferromagnet forming the recording layers 70, 70a is CoFeB. The recording layers 70, 70a are not essentially formed of CoFeB and can be formed suitably of a ferromagnet containing at least one of Co, Ni and Fe. For example, the recording layers 70, 70a may be a Co layer, Ni layer, Fe layer, NiFe layer, CoFe layer, CoNi layer, CoNiFe layer or others.

In the above-described embodiments, the ferromagnet forming the recording layers 70, 70a is CoFeB. However, the recording layers 70, 70a are not formed essentially of CoFeB. The recording layers 70a, 70a may be formed of a vertical magnetic recording material such as FePt, CoPt, CoCrPt or others.

In the above-described embodiments, the ferromagnetic layer 38 forming a part of the fixed magnetization layer 32 is CoFe. However, the ferromagnetic layer 38 is not formed essentially of CoFe. The ferromagnetic layer 38 can be formed suitably of a ferromagnet containing at least one of Co, Ni and Fe. For example, the ferromagnetic layer 38 may be a Co layer, Ni layer, Fe layer, NiFe layer, CoFeB layer, CoNi layer, CoNiFe layer or others.

In the above-described embodiments, the ferromagnetic layer 42 forming a part of the fixed magnetization layer 32 is CoFe. However, the ferromagnetic layer 42 is not formed essentially of CoFe. The ferromagnetic layer 42 can be formed suitably of a ferromagnet containing at least one of Co, Ni and Fe. For example, the ferromagnetic layer 42 may be a Co layer, Ni layer, Fe layer, NiFe layer, CoFeB layer, CoNi layer, CoNiFe layer or others.

In the above-described embodiments, the anti-ferromagnetic layer 36 forming a part of the fixed magnetization layer 32 is formed of IrMn, PtMn or others. However, the anti-ferromagnetic layer 36 is not formed essentially of IrMn or PtMn. For example, the anti-ferromagnetic layer 36 may be formed of an anti-ferromagnetic material, such as PdPtMn or others.

In the above-described embodiments, the non-magnetic layer 40 forming a part of the fixed magnetization layer 32 is formed of Ru, Rh or Cr. However, the non-magnetic layer 40 is not essentially formed of Ru, Rh or Cr. For example, the non-magnetic layer 40 may be formed of a non-magnetic material, such as Cu, Al, Au or others.

In the above-described embodiments, the barrier layer (tunnel insulation film) 34 is formed of Al₂O₃. However, the barrier layer 34 is not essentially formed of Al₂O₃. For example, the barrier film 34 may be formed suitably of an insulation material, such as MgO, HfOx, TiOx, TaOx or others.

In the above-described embodiments, the writing element 4 is the interconnection 58. However, the writing element 4 is not essentially the interconnection 58. The writing element 4 may be, e.g., a TMR element or a GMR element.

In the above-described embodiments, the reading element 2 is a TMR element. However, the reading element 2 is not essentially a TMR element. The reading element 2 may be, e.g., a GMR element.

What is claimed is:

1. A magnetic memory device comprising a recording layer formed linearly over a substrate, a plurality of pinning sites for restricting motion of domain walls being formed in the recording layer at a prescribed pitch, and regions between said plurality of pinning sites being a plurality of recording bits,
the recording layer including a first recording layer portion and a second recording layer portion, the second recording layer portion being positioned above the first recording layer portion, and one end of the second recording layer portion being connected to one end of the first recording layer portion.

2. A magnetic memory device according to claim 1, wherein
a length of the first recording layer portion and a length of the second recording layer portion are substantially equal to each other.

3. A magnetic memory device according to claim 1, further comprising
a writer located near the part where the first recording layer portion and the second recording layer portion are connected to each other and opposed to one of said plurality of recording bit.

4. A magnetic memory device according to claim 3, wherein
the writer is an interconnection.

5. A magnetic memory device according to claim 1, further comprising
a reader located near the part where the first recording layer portion and the second recording layer portion are connected to each other and opposed to one of said plurality of recording bits.

6. A magnetic memory device according to claim 5, wherein
the reader is a magnetoresistance effect element.

7. A magnetic memory device comprising
a recording layer formed linearly over a substrate, a plurality of pinning sites for restricting motion of domain walls being formed in the recording layer at a prescribed pitch, and regions between said plurality of pinning sites being a plurality of recording bits,
the recording layer including a first recording layer portion and a second recording layer portion arranged side by side with respect to a plane of the substrate, and one end of the first recording layer portion and one end of the second recording layer portion being connected to each other.

8. A magnetic memory device according to claim 7, further comprising
a writer opposed to one of said plurality of recording bits.

9. A magnetic memory device according to claim 8, wherein
the writer is an-interconnection.

10. A magnetic memory device according to claim 7, further comprising
a reader opposed to one of said plurality of recording bits.

11. A magnetic memory device according to claim 10, wherein
the reader is a magnetoresistance effect element.

12. A magnetic memory device according to claim 1, wherein
the recording layer is formed of a ferromagnet containing at least one of Co, Fe and Ni.

13. A magnetic memory device according to claim 1, wherein
the recording layer is formed of FePt, CoPt or CoCrPt.

14. A magnetic memory device according to claim 1, wherein
the pinning sites are defined by notches formed in the side of the recording layer.

15. A method for fabricating a magnetic memory device comprising the steps of:
forming the first recording layer linearly over a substrate, pinning sites for restricting the motion of domain walls being formed in the first recording layer at a prescribed pitch;
etching the region of the first recording layer except one end thereof to a prescribed thickness;
forming an insulation layer burying the first recording layer; and
forming the second recording layer linearly over the insulation layer in the region above the first recording layer, the second recording layer being connected to said one end of the first recording layer, and pinning sites for restricting motion of domain walls being formed in the second recording layer at said prescribed pitch.

16. A method for fabricating a magnetic memory device comprising the step of forming a recording layer linearly over a substrate, pinning sites for restricting motion of domain walls being formed in the recording layer at a prescribed pitch,
the recording layer including a first recording layer portion and a second recording layer portion arranged side by side with respect to a plane of the substrate, and one end of the first recording layer portion and one end of the second recording layer portion being connected to each other.
